(19) United States
(12) Patent Application Publication
(10) Pub. No.: US 2013/0039041 A1
(43) Pub. Date: Feb. 14, 2013

(54) LIGHTING DEVICE FOR DIRECT AND INDIRECT LIGHTING

(71) Applicants: Wei-Yu YEH, Tainan City (TW); Pei-Wen KO, Zhubei City (TW)

(72) Inventors: Wei-Yu YEH, Tainan City (TW); Pei-Wen KO, Zhubei City (TW)

(73) Assignee: TAIWAN SEMICONDUCTOR MANUFACTURING COMPANY, LTD., Hsinchu (TW)

(21) Appl. No.: 13/209,258

(22) Filed: Aug. 12, 2011

(51) Int. Cl. F21S 8/04; H05K 13/04; H05K 3/30; F21V 21/02; F21V 29/00

(52) U.S. Cl. 362/147; 362/249.02; 29/832; 29/841

(57) ABSTRACT

A lighting device includes at least one heat sink. At least two light emitting diode (LED) modules are mounted on the at least one heat sink. The at least two LED modules are mounted at different directions on the at least one heat sink so that a first LED module of the at least two LED modules generally radiates lights in a first direction for a direct lighting and a second LED module of the at least two LED modules generally radiates light in a second direction for an indirect lighting by reflecting on a surface.

### TECHNICAL FIELD

The present disclosure relates generally to a lighting device and, more particularly, to a lighting device using light emitting diodes (LEDs).

### BACKGROUND

For some lighting applications, e.g., domestic lighting, direct and indirect lighting have different purposes. For example, direct lighting is used for reading, while indirect lighting is used to provide a comfortable atmosphere. More light emitting diodes (LEDs) are used nowadays for many lighting applications, including domestic lighting. Direct lighting and indirect lighting using LEDs are provided by separate lighting devices with different layouts, which can be costly and inconvenient.

### BRIEF DESCRIPTION OF THE DRAWINGS

Reference is now made to the following descriptions taken in conjunction with the accompanying drawings, in which:

FIG. 1A is a cross-sectional view of an exemplary lighting device according to some embodiments;

FIG. 1B is a cross-sectional view of an exemplary light emitting diode (LED) module for the lighting device in FIG. 1A according to some embodiments;

FIG. 1C is a cross-sectional view of another exemplary lighting device according to some embodiments;

FIGS. 2A-2E are 2-dimensional views of exemplary lighting device layouts according to some embodiments; and

FIGS. 3A-3C are schematic diagrams at various stages of fabricating the lighting device in FIG. 1A according to some embodiments.

### DETAILED DESCRIPTION

The making and using of various embodiments are discussed in detail below. It should be appreciated, however, that the present disclosure provides many applicable inventive concepts that can be embodied in a wide variety of specific contexts. The specific embodiments discussed are merely illustrative of specific ways to make and use, and do not limit the scope of the disclosure.

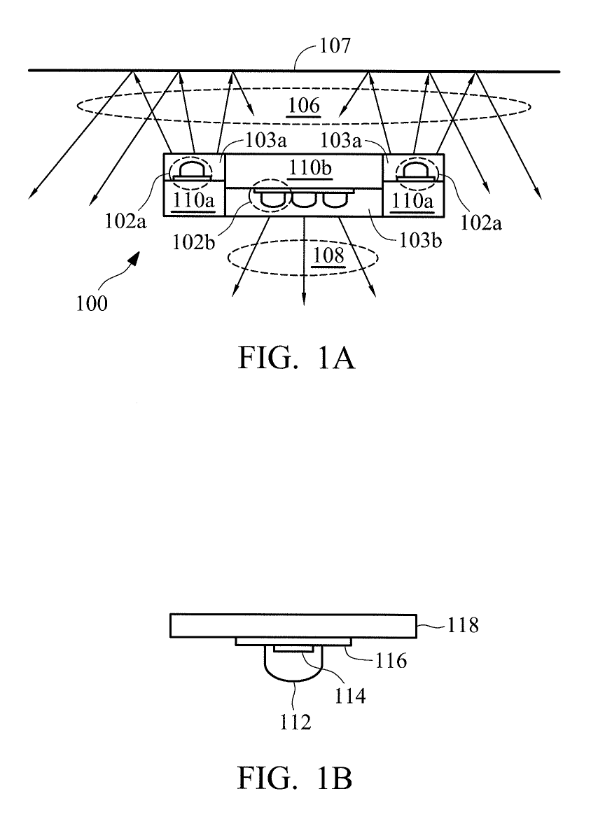

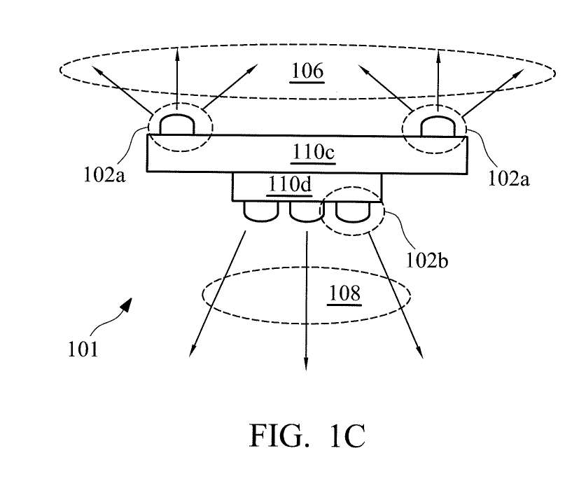

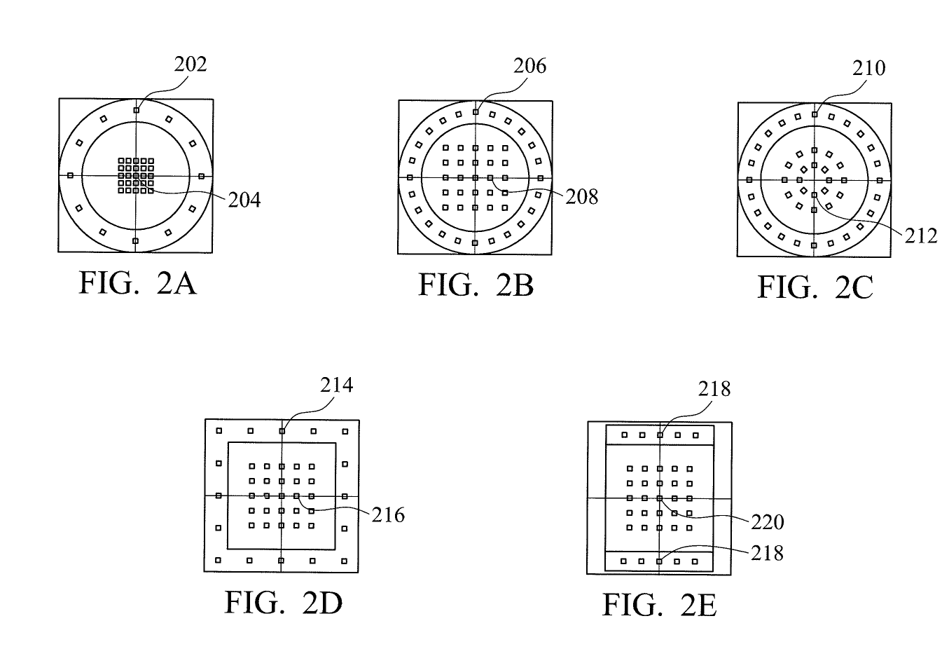

FIG. 1A is a cross-sectional view of an exemplary lighting device 100 according to some embodiments. The lighting device 100 includes LED modules 102a and 102b. Some LED modules 102a are mounted on the heat sink 110a at angles such that indirect lighting 106 from reflection of lights on surfaces such as a ceiling 107 is provided by the LED modules 102a. Other LED modules 102b are mounted on the heat sink 110b such that direct lighting 108 is provided by the LED modules 102b. In general, the LED modules 102a and 102b can be mounted (e.g., on the heat sink 110a and 110b) for radiating lights generally at different directions, and not necessarily at opposite directions.

Light caps 103a and 103b are used to cover (enclose) the LED modules 102a and 102b. The light caps 103a and 103b can have arbitrary shapes and colors, which may be transparent, semitransparent, or partially transparent, etc., depending on applications. The heat sinks 110a and 110b can be one piece or multiple pieces held together (by bonding or by other mechanical means), depending on appearance and mechanical design. Good thermal management could be achieved by various arrangements of heat sinks 110a and 110b with different shapes, e.g., circular, square, rectangular, ring, band, linear, etc.

The lighting device 100 can be mechanically fixed in various ways, e.g., hung from the ceiling, mounted on a pole or stand (not shown), etc. The lighting device 100 with the LED modules 102a and 102b mounted at different directions is suited for multi-directional lighting applications. In particular, the double-sided design shown in FIG. 1A is suited for radiating light from both surfaces, e.g., for direct and indirect lighting applications. The LED modules 102a and 102b can be turned on or off with various sequential algorithms. For example, the lighting sequence can be controlled according to the following table.

TABLE 1

| Sequence | Direct | Indirect |
|---|---|---|
| 1 | On | Off |
| 2 | Off | On |
| 3 | On | On |
| 4 | Off | Off |

According to table 1, only direct lighting LED modules such as 102b are turned on at the first setting in the sequence, e.g., with a switch or button operation. At the second setting in the sequence, only indirect lighting LED modules such as 102a are turned on. At the third setting in the sequence, both are turned on, and at the fourth setting in the sequence, both are turned off. There can be many variations on the operation of the settings in the sequence. For example, there can be more settings in the sequences than just four settings as in Table 1, and the controlled units can be different (e.g., half of the direct lighting LED modules can be controlled separately from the other half of the direct lighting LED modules, etc.)

FIG. 1B is a cross-sectional view of an exemplary light emitting diode (LED) module for the lighting device in FIG. 1A according to some embodiments. An LED chip 114 is mounted on a substrate 116, which is in turn mounted on a printed circuit board (PCB) 118. An LED lens 112 encapsulates the LED chip 114. The LED chip 114 can be any color LED comprising different materials. For example, the LED chip 114 may include GaN for Blue/Green color, AlInGaP for Yellow/Red, etc. The LED chip 114 may have different sizes (e.g., dimensions of about 4×4 mm², or dimensions could be larger or smaller) with different thicknesses (e.g., about 100 μm, although the thickness could be thicker or thinner than 100 μm).

The substrate 116 could comprise silicon, ceramic, or any other suitable material. In some embodiments, a complex integrated circuit with LED or other detector circuit can be fabricated based on silicon processes. The substrate 116 can have different thicknesses, e.g., about 400 μm (but could be thicker or thinner). The substrate 116 is mounted on the PCB 118. In various embodiments, different PCBs, e.g., a PCB including FR-4, an Al-based metal core PCB (MCPCB), or Cu-based MCPCB, or any other kinds of PCB can be used. The PCB allows easier installation of the LED module and for effective thermal-conductive function.

The heat sinks 110a and 110b can comprise Al, Cu, Ag, Fe, any combination thereof, or any other suitable material. The dimension of the heat sinks 110a and 110b depends on specifications (e.g., how much power or heat, temperature requirements, etc.). For example, a 10 W LED source may need greater than 30000 mm² of heat spreading in some embodiments.

FIG. 1C is a cross-sectional view of another exemplary lighting device 101 according to some embodiments. For the lighting device 101, LED modules 102a are mounted on a heat sink 110c and LED modules 102b are mounted on the heat sink 110d. The heat sinks 110c and 110d are bonded on the backside of each other, and the LED modules 102a and 102b are facing the opposite directions for different directional lighting (e.g., for direct lighting 108 and also indirect lighting 106 by reflecting on another surface, such as ceiling, which is not shown.)

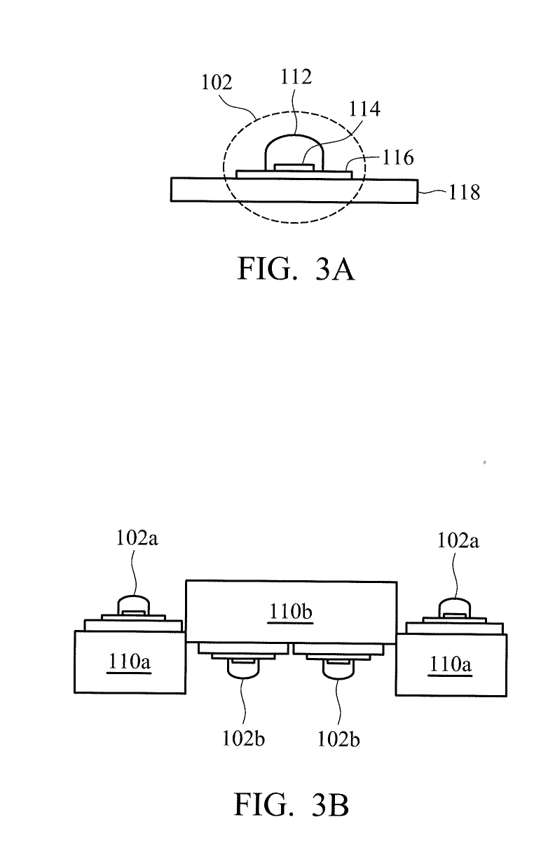

FIGS. 2A-2E are 2-dimensional views of exemplary lighting device layouts according to some embodiments. In FIG. 2A, outside LED modules 202 are arranged in a ring shape, while inside LED modules 204 are arranged in a square array concentrated in the center. The inside LED modules 204 and outside LED modules 202 are mounted on opposite sides for different lighting directions, e.g., for direct and indirect lighting. In FIG. 2B, outside LED modules 206 are also arranged in a ring shape with more numbers than FIG. 2A, while inside LED modules 208 are arranged in a square array more spread out compared to FIG. 2A.

In FIG. 2C, outside LED modules 210 are also arranged in a ring shape, while inside LED modules 212 are arranged in a circular pattern. In FIG. 2D, outside LED modules 214 are arranged in a square band shape, while inside LED modules 216 are arranged in a square array. In FIG. 2E, outside LED modules 218 are arranged in a linear shape on two opposite edges, while inside LED modules 220 are arranged in a square array. The inside LED modules and outside LED modules in the examples in FIGS. 2A-2E are mounted on opposite sides for different lighting directions, e.g., for direct and indirect lighting.

The arrangement scheme can be varied and there can be different mixing of LED modules for different lighting directions, e.g., a part of inside LED modules 204 can be mounted on the same side as the outside LED modules 202 for a different lighting direction from the rest of the inside LED modules 204 (i.e., the same lighting direction as the outside LED modules 202). There can be many other variations with different shapes such as triangular, rectangular, oval, star-shape, etc. for different arrangements.

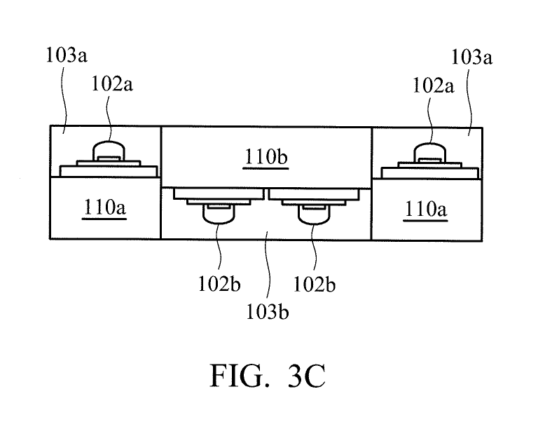

FIGS. 3A-3C are schematic diagrams at various stages of fabricating the lighting device in FIG. 1A according to some embodiments. In FIG. 3A, the LED module 102 is mounted on the PCB 118. A surface-mount technology (SMT), e.g., soldering, can be used for this step. The LED module 102 includes the LED chip 114, the substrate (sub-mount) 116, and the LED lens 112. The LED chip 114 is bonded (mounted) on the substrate 116 prior to this step, e.g., by soldering. The LED lens 112 can be formed (molded) either before or after this step.

In FIG. 3B, the LED modules 102a are mounted on the heat sink 110a, while the LED modules 102b are mounted on the heat sink 110b at different (e.g., opposite) directions. The LED modules 102a and 102b are bonded by a thermal interface layer (not shown) using heat-dissipating material with good thermal conductivity such as a thermal grease layer, a thermal pad, or any other suitable thermal interface material. The heat sinks 110a and 110b may be one piece or multiple pieces held together (by bonding or by other mechanical means), depending on the appearance and mechanical design of the lighting device.

For example, the thermal grease can be ceramic-based, metal-based, carbon based, liquid metal based, etc. Ceramic-based thermal grease is a ceramic powder suspended in a liquid or gelatinous silicone compound, which may be described as silicone paste or silicone thermal compound, e.g., beryllium oxide, aluminum nitride, aluminum oxide, zinc oxide, and silicon dioxide. Metal-based thermal grease contain solid metal particles (usually silver or aluminum). Carbon based thermal grease may contain diamond powder or short carbon fibers. A liquid metal based thermal grease contains liquid metal alloys, e.g., of gallium.

In FIG. 3C, the LED modules 102a and 102b are covered by light caps 103a and 103b, which can have arbitrary shapes and colors, and may be transparent, semitransparent, or partially transparent, etc. depending on applications. The light caps 103a and 103b can comprise plastic, glass material, or any other suitable material.

According to some embodiments, a lighting device includes at least one heat sink. At least two light emitting diode (LED) modules are mounted on the at least one heat sink. The at least two LED modules are mounted at different directions on the at least one heat sink so that a first LED module of the at least two LED modules generally radiates lights in a first direction for a direct lighting and a second LED module of the at least two LED modules generally radiates lights in a second direction for an indirect lighting by reflecting on a surface.

According to some embodiments, a method of fabricating a lighting device includes mounting at least two light emitting diode (LED) chips on substrates for forming at least two LED modules. At least two LED modules are mounted at different directions on at least one heat sink so that a first LED module of the at least two LED modules generally radiates lights in a first direction for a direct lighting and a second LED module of the at least two LED modules generally radiates lights in a second direction for an indirect lighting by reflecting on a surface.

A skilled person in the art will appreciate that there can be many embodiment variations of this disclosure. Although the embodiments and their features have been described in detail, it should be understood that various changes, substitutions and alterations can be made herein without departing from the spirit and scope of the embodiments. Moreover, the scope of the present application is not intended to be limited to the particular embodiments of the process, machine, manufacture, and composition of matter, means, methods and steps described in the specification. As one of ordinary skill in the art will readily appreciate from the disclosed embodiments, processes, machines, manufacture, compositions of matter, means, methods, or steps, that perform substantially the same function or achieve substantially the same result as the corresponding embodiments described herein may be utilized according to the present disclosure.

The above method embodiment shows exemplary steps, but they are not necessarily required to be performed in the order shown. Steps may be added, replaced, changed order, and/or eliminated as appropriate, in accordance with the spirit and scope of embodiment of the disclosure. Embodiments that combine different claims and/or different embodiments are within the scope of the disclosure and will be apparent to those skilled in the art after reviewing this disclosure.

What is claimed is:

1. A lighting device, comprising:
at least one heat sink; and
at least two light emitting diode (LED) modules mounted on the at least one heat sink,
wherein the at least two LED modules are mounted at different directions on the at least one heat sink so that a first LED module of the at least two LED modules generally radiates lights in a first direction for a direct lighting and a second LED module of the at least two LED modules generally radiates lights in a second direction for an indirect lighting by reflecting on a surface.

2. The lighting device of claim 1, wherein the surface is a ceiling.

3. The lighting device of claim 1, wherein the first direction and the second direction are opposite directions from each other.

4. The lighting device of claim 1, wherein each LED module of the at least two LED modules comprises a substrate and an LED chip mounted on the substrate.

5. The lighting device of claim 4, wherein each LED module further comprises a printed circuit board (PCB), and the substrate is mounted on the PCB.

6. The lighting device of claim 5, wherein the PCB comprises a metal core PCB.

7. The lighting device of claim 5, wherein each LED module further comprises an LED lens encapsulating the LED chip.

8. The lighting device of claim 5, wherein a thermal grease material bonds the PCB and the heat sink.

9. The lighting device of claim 1, wherein multiple LED modules of the at least two LED modules generally radiating lights in the first direction are arranged on an outer region of the lighting device.

10. The lighting device of claim 9, wherein multiple LED modules the at least two LED modules generally radiating lights in the second direction are arranged on an inner region of the lighting device.

11. The lighting device of claim 1, further comprising at least one light cap that encloses the at least two LED modules.

12. A method of fabricating a lighting device, comprising:
mounting at least two light emitting diode (LED) chips on substrates for forming at least two LED modules; and
mounting at least two LED modules at different directions on at least one heat sink so that a first LED module of the at least two LED modules generally radiates lights in a first direction for a direct lighting and a second LED module of the at least two LED modules generally radiates lights in a second direction for an indirect lighting by reflecting on a surface.

13. The method of claim 12, further comprising mounting the substrates on printed circuit boards (PCBs).

14. The method of claim 12, further comprises encapsulating the LED chips with LED lenses.

15. The method of claim 12, wherein the at least two LED modules are mounted on the at least one heat sink by applying a thermal grease material.

16. The method of claim 12, wherein the first direction and the second direction are opposite directions from each other.

17. The method of claim 12, further comprising arranging multiple LED modules of the at least two LED modules generally radiating lights in the first direction on an outer region of the lighting device.

18. The method of claim 12, further comprising arranging multiple LED modules of the at least two LED modules generally radiating lights in the second direction on an inner region of the lighting device.

19. The method of claim 12, further comprising enclosing the at least two LED modules with at least one light cap.

20. A lighting device, comprising:
at least one heat sink;
at least two light emitting diode (LED) modules mounted on the at least one heat sink; and
at least one light cap that encloses the at least two LED modules,
wherein the at least two LED modules are mounted at different directions on the at least one heat sink so that a first LED module of the at least two LED modules generally radiates lights in a first direction for a direct lighting and a second LED module of the at least two LED modules generally radiates lights in a second direction opposite to the first direction for an indirect lighting by reflecting on a surface.
